(19) United States
(12) Patent Application Publication
(10) Pub. No.: US 2019/0003904 A1
(43) Pub. Date: Jan. 3, 2019

(54) FLAT BUILT TEMPERATURE CONTROL UNIT FOR BATTERY TEMPERATURE MONITORING

(71) Applicant: IEE INTERNATIONAL ELECTRONICS & ENGINEERING S.A., Echternach (LU)

(72) Inventors: Baptiste FAGART, Longwy (FR); Guy WATHIEU, Bridel (LU); Dietmar JUNGEN, Mehren (DE); Christian REICH, Schweich (DE)

(21) Appl. No.: 16/065,493

(22) PCT Filed: Dec. 15, 2016
(86) PCT No.: PCT/EP2016/081241

§ 371 Date: Jun. 22, 2018

(30) Foreign Application Priority Data
Dec. 24, 2015 (LU) 92932

(51) Int. Cl. G01K 13/10; G01R 31/36; H01M 10/48; H01M 10/0525; H01M 10/6563

(52) U.S. Cl. CPC G01K 13/10; G01R 31/3606; G01K 2205/00; H01M 10/0525; H01M 10/6563; H01M 10/486

(57) ABSTRACT

A flat built temperature control unit for use in a rechargeable battery unit, in particular a rechargeable lithium ion battery. The temperature control unit includes at least one temperature sensor arranged on one of the surfaces of a first electrically insulating sheet. A plurality of first electrically conductive tracks electrically connects the at least one temperature sensor to a plurality of electrically conductive contact members. A rechargeable electrochemical battery unit, in particular for automotive applications, comprises at least one battery block including a plurality of stacked battery cells, at least one disclosed temperature control unit, and a control unit that is configured for receiving an output signal of at least one temperature sensor and for controlling operation of at least one out of cooler and heater based on the received output signal and on fulfillment of at least one predetermined condition.

### TECHNICAL FIELD

The invention relates to a flat built temperature control unit for use in a rechargeable battery comprising at least one stacked battery block, and a rechargeable electrochemical battery unit, in particular for automotive applications, including at least one such temperature control unit.

### BACKGROUND OF THE INVENTION

In the field of rechargeable batteries, in particular for automotive applications, it is well known that proper battery temperature management is crucial for maintaining high performance and longevity. Battery temperature management requires monitoring battery temperature at appropriate locations for control purposes, for instance for triggering a battery cooling system.

For example, patent application publication US 2014/0377598 A1 describes a battery for a motor vehicle. The battery comprises at least one battery cell or a plurality of battery cells, preferably a lithium-ion battery cell, which has a housing with an electrode arrangement arranged therein. A first temperature sensor is arranged outside the battery cell housing, and at least one of the battery cells has a second temperature sensor arranged inside the housing of the relevant battery cell. The temperature dynamic of the second temperature sensor is higher than the temperature dynamic of the first temperature sensor. Moreover, a third temperature sensor can be arranged in a cooling system of the battery cells in the battery. As a result of the detection of the housing interior temperature, a battery model in the battery control unit can be parameterized more accurately and be evaluated better for simulation and state identification and prediction purposes. The respective temperature sensors are described to be designed as NTC thermistor, PTC thermistor or differential temperature sensor.

One of the development targets in the field of rechargeable batteries, in particular for automotive applications, is volumetric power density. From this requirement, in general very little space is available for auxiliary sensors such as temperature sensors, and electronics intended for being positioned inside a housing of a battery.

Further requirements concerning mechanical properties and manufacturing tolerances in a dimension of thickness for sensor and electronic components arise from existing conditions inside a battery housing during operation, as these components usually needs to be fixedly attached to the battery cells in an installed state, in which compression loads of typically 15 kN are applied to stacked battery cells, for instance by use of tie-rods or metal bands.

Further, operating conditions within a housing of a battery are known to be highly corrosive, by which high requirements are set with regard to corrosion resistance for reliable operation of the temperature control unit.

### SUMMARY

It is therefore an object of the invention to provide a temperature control unit that at least enables temperature sensing inside a battery housing with reduced space requirements and at the same time meets the above-mentioned requirements.

In one aspect of the present invention, the object is achieved by a flat built temperature control unit for use in a rechargeable battery unit comprising at least one stacked battery block, in particular a rechargeable lithium ion battery, wherein the temperature control unit comprises
at least a first electrically insulating sheet having even, parallel surfaces,
at least one temperature sensor, arranged on one of the surfaces of the first electrically insulating sheet,
a plurality of electrically conductive contact members, and
a plurality of first electrically conductive tracks that are arranged on a surface of the first electrically insulating sheet.

The at least one temperature sensor is electrically connected by electrically conductive tracks of the plurality of first electrically conductive tracks to contact members of the plurality of electrically conductive contact members.

The temperature sensor is configured for providing a temperature sensor output signal that is indicative of a temperature of the rechargeable battery at the location of the temperature control unit. The temperature sensor output signal can be transferred to a control unit for temperature control purposes. It should be noted that the temperature sensor may be combined with an electric heater member configured for heating up battery cells of the rechargeable battery to a nominal operation temperature which is known to be beneficial for battery performance. An electric current to be provided to the electric heater member can be controlled by the control unit or can be provided to the electric heater member and can be controlled by the electrical heating member itself.

The term “electrically connected”, as used in this application, shall be understood to encompass galvanic electrical connections as well as connections established by capacitive and/or inductive electromagnetic coupling.

It is further noted herewith that the terms “first”, “second”, etc. are used in this application for distinction purposes only and are not meant to indicate or anticipate a sequence or a priority in any way.

In this way, a compact design of the temperature control unit can be accomplished especially in a direction extending perpendicularly to the surfaces of the first electrically insulating sheet, which corresponds to a preferred direction for stacking battery blocks. As a result, an effect of an installed temperature control unit on a volumetric power density of the rechargeable battery can be kept small.

In a preferred embodiment, a total height, as measured in a direction perpendicular to the surfaces of the first electrically insulating sheet, of the at least one temperature sensor, an electrically conductive track that is electrically connected to the at least one temperature sensor and the first electrically insulating sheet is less than or equal to 1.0 mm.

In this way, a large number of design options for placing the temperature control unit within a housing of the rechargeable battery can be provided, and the volumetric power density of the battery can be maintained almost unaffected.

In another preferred embodiment, the at least first electrically insulating sheet has a basically oblong shape and the plurality of electrically conductive contact members is arranged on the surface of the first electrically insulating sheet and at an end region of the basically oblong shape. In this way, sensor output signals of the temperature sensor or an electric current to be provided to the electric heater member can readily be transferred from an outer/peripheral region of the battery to a core/center region of the battery, which in general is a priority region for sensing temperature or for warming up the battery.

If the at least one temperature sensor is a surface-mounted device temperature sensor with negative temperature coefficient (NTC), a cost-effective temperature control unit with a low total height can be provided.

In some embodiments, the temperature sensor is combined with at least one electric heater member. In this case the temperature control unit further comprises at least one heater element arranged on one of the surfaces of the first electrically insulating sheet and the at least one heater element is preferably electrically connected by electrically conductive tracks of the plurality of first electrically conductive tracks to contact members of the plurality of electrically conductive contact members. In embodiments thereof, the at least one electric heater member comprises a material having an electrical resistivity with a positive temperature coefficient (PTC). Preferably, the at least one electric heater member is formed by a PTC thermistor. In this way, an inherently safe solution for warming up battery cells of the battery can be provided.

In one embodiment, the at least one out of a temperature sensor and an electric heater member comprises an electrically insulating cover that is at least arranged on and adhesively attached to a portion of the at least one temperature sensor that is facing away from the first electrically insulating sheet. In this way, an efficient corrosion protection can be provided for the at least one temperature sensor. In a variant of this embodiment, the electrically insulating cover may be recessed in the area of the temperature sensor the electrically insulating cover has a thickness that is equal to or higher than a height of the temperature sensor. This configuration, in which the height of the temperature sensor is equal or less than the thickness of the electrically insulating cover, effectively allows to prevent damages of the battery cell due to sharp edges of the temperature sensor.

Further corrosion protection can be provided if at least the first electrically conductive tracks of the plurality of first electrically conductive tracks that are electrically connected to the at least one out of a temperature sensor and an electric heater member are at least partially covered by an electrically insulating coating.

In yet another preferred embodiment, the temperature control unit further comprises a plurality of electrically conductive terminal members, each electrically connectable terminal member of the plurality of electrically conductive terminal members being electrically connected to at least one of the electrically conductive tracks of the plurality of first of electrically conductive tracks. The plurality of electrically conductive terminal members is arranged in a coplanar manner, wherein the plane of arrangement is disposed to substantially form a right angle with the bottom surface of the second electrically insulating sheet.

In this way, an interface for transferring temperature sensor output signals to the outside of the battery cells and/or for providing an electric current to the electric heater member from outside of the battery cells to the core region of the battery cells can readily be provided.

Further, the plurality of electrically conductive terminal members can ensure electrical and mechanical connections to an electronic control unit.

In one embodiment, the temperature control unit further comprises a second electrically insulating sheet having a main sheet with even surfaces, arranged in parallel to each other, and an edge sheet member that is located at an edge of the main sheet. The first electrically insulating sheet is attached on a top surface of the second electrically insulating sheet. The second electrically insulating sheet overlaps the first electrically insulating sheet in a direction perpendicular to the surface of the first electrically insulating sheet. A surface of the edge sheet member is aligned in parallel to and abuts the plurality of electrically conductive terminal members.

In this way, a high mechanical stability of the temperature control unit and an appropriate mechanical support of the electrically conductive terminal members can be accomplished and high longevity can be achieved.

Preferably, the main sheet and the edge sheet member are integrally formed as one part, by which a mechanically highly stable and cost-effective solution can be provided.

In some embodiments of the temperature control unit, a most part of at least one of the first electrically insulating sheet and the second electrically insulating sheet is made from a plastic material that is selected from a group of plastic materials including, but not limited to, polyethylene terephthalate (PET), polyimide (PI), polyetherimide (PEI), polyethylene naphthalate (PEN), polyoxymethylene (POM), polamide (PA), polyphthalamide (PPA), polyether ether ketone (PEEK) and combinations of at least two of these plastic materials. The term “most part of”, as used in this application, shall particularly be understood as equal to or more than 50%, more preferably more than 70%, and, most preferably, more than 80% in volume, and shall encompass a part of 100%, i.e. completely.

These materials allow for easy manufacturing, and durable, cost-efficient electrically insulating sheets of low manufacturing tolerances can be provided.

These benefits can further be enhanced if at least one out of the plurality of electrically conductive contact members, the plurality of first electrically conductive tracks and the plurality of second electrically conductive tracks comprises cured electrically conductive ink. In this way, an application of high-precision manufacturing methods such as screen printing and ink jet printing is facilitated, resulting in low manufacturing tolerances, in particular of dimensions in the direction perpendicular to the surfaces of the first electrically insulating sheet or the second electrically insulating sheet. Low manufacturing tolerances in this dimension can enable a uniform compression load in a compressed state of the temperature control unit.

Preferably, the cured electrically conductive ink comprises silver.

In another aspect of the invention, a rechargeable electrochemical battery unit, in particular for automotive applications, is provided. The battery unit comprises
at least one battery block that includes a plurality of stacked battery cells,
at least one embodiment of a temperature control unit in accordance with the invention as disclosed herein, and
a control unit that is configured for receiving an output signal of at least one temperature sensor and for controlling operation of at least one out of cooling means and heater means based on the received output signal and on fulfillment of at least one predetermined condition.

By that, the advantages presented for the temperature control unit in accordance with the invention also apply to the rechargeable electrochemical battery unit.

### BRIEF DESCRIPTION OF THE DRAWINGS

Further details and advantages of the present invention will be apparent from the following detailed description of not limiting embodiments with reference to the attached drawing, wherein:

FIG. 1 schematically illustrates a battery unit for automotive applications, including a temperature control unit in accordance with an embodiment of the invention;

FIG. 2 is a plan view of the temperature control unit pursuant to FIG. 1, including magnified details;

FIG. 3 is a perspective view of an alternative temperature control unit in accordance with another embodiment of the invention;

FIG. 4 is a perspective view of another alternative temperature control unit in accordance with yet another embodiment the invention; and

FIG. 5 is a cross-sectional side view of a detail of the alternative temperature control unit pursuant to FIG. 4.

### DESCRIPTION OF THE ILLUSTRATED EMBODIMENTS

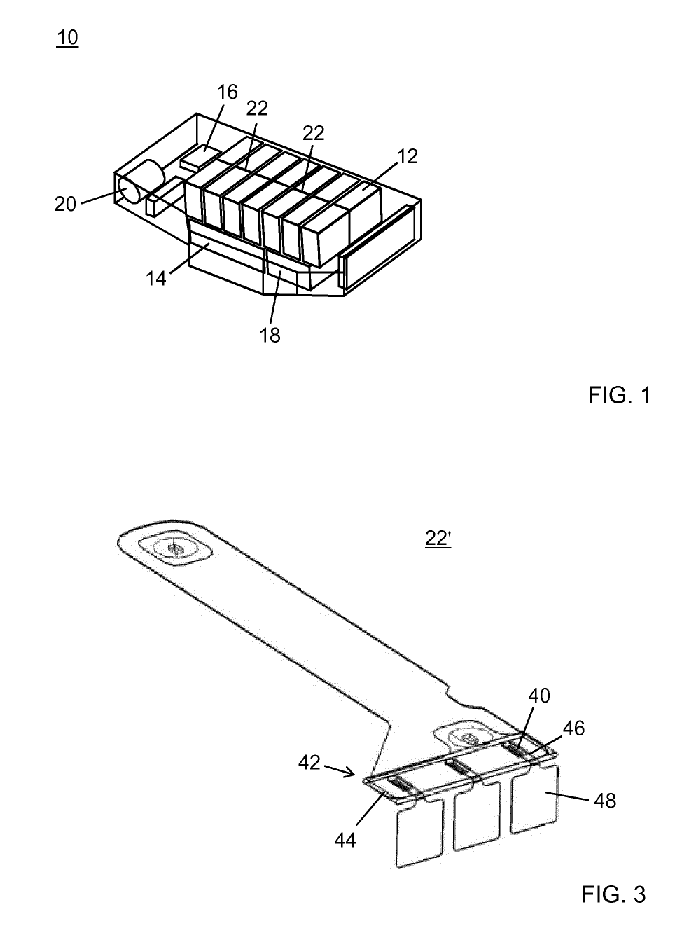

FIG. 1 schematically illustrates an assembly of a rechargeable electrochemical battery unit 10, namely a lithium ion battery unit for automotive application. In an operation state, the assembly is contained in a housing of the battery unit 10, which is not completely shown in FIG. 1 for clarity purposes. The battery unit 10 comprises a plurality of seven battery blocks 12, each battery block 12 including a plurality of stacked battery cells, wherein the battery blocks 12 are tightly packed in a parallel and juxtaposed manner. The battery unit 10 further includes a power electronics unit 14, make-break switches 18 electrically connected to the plurality of battery blocks 12, as is well known in the art, and cooling means formed by an air blower 20 for cooling the battery blocks 12.

Furthermore, the battery unit 10 includes a plurality of seven temperature control units 22. One temperature control unit 22 each is installed in each of the seven battery blocks 12. The temperature control units 22 are especially configured to be connected to a cell frame of the battery block 12. The fixation of each temperature control unit 22 is established by the compressed block 12 of stacked battery cells. Thereby, each of the temperature control units 22 is exposed to a uniform compression load of up to 15 kN in the installed situation.

The battery unit 10 also comprises a control unit 16 that is configured to receive output signals provided by the temperature control units 22 and is configured to control operation of the air blower 20 for cooling the plurality of battery blocks 12 or a heater element for heating the battery assembly, as will be described below.

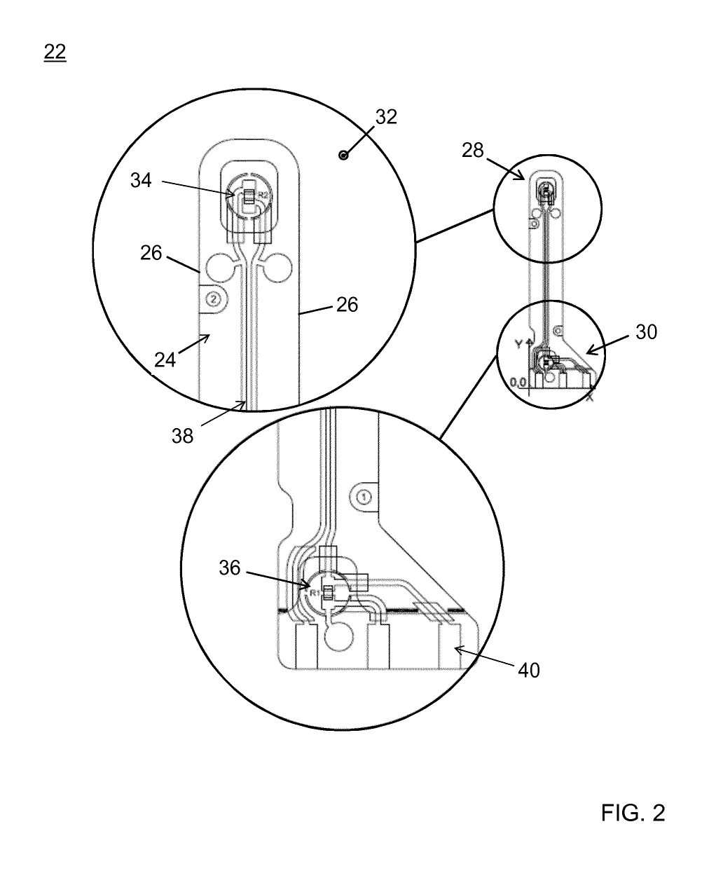

A plan view of one of the temperature control units 22 pursuant to FIG. 1 is shown in FIG. 2, including magnified details. As the temperature control units 22 are all identically designed, it is sufficient to describe the features of the temperature control units 22 with reference to one of the temperature control units 22 as an example.

The flat built temperature control unit 22 comprises a first electrically insulating sheet 24 having even surfaces, which are substantially arranged in parallel, and have a basically oblong shape. The oblong shape has two longer edges 26 starting at one rounded end 28 of the oblong shape that run in parallel for most of a length of the oblong shape, and a widened, trapezoidal region forming another end 30 of the oblong shape. The first electrically insulating sheet 24 is completely made from polyethylene terephthalate (PET) and has a thickness, as measured in a direction perpendicular to its surfaces, of 125 μm.

The temperature control unit 22 further includes two temperature sensors 34, 36. One temperature sensor 34, 36 each of the two temperature sensors 34, 36 is arranged at each end 28, 30 of the oblong shape of the first electrically insulating sheet 24. The temperature sensors 34, 36 are formed by surface-mount device (SMD) NTC temperature sensors.

In an alternative embodiment, which is not shown in the figures, the temperature control unit 22 may include only one surface-mount device NTC temperature sensor and, instead of a second temperature sensor, a heater member comprising a material having a positive temperature coefficient (PTC) electrical resistivity. As is known in the art, the heater member may be designed as an electrically resistive metal track that is arranged in a plane in a meandering way and that may be attached to the first electrically insulating sheet 24 by using an adhesive.

Then, the temperature control unit 22 comprises a plurality of first electrically conductive tracks 38 that are arranged on one of the surfaces of the first electrically insulating sheet 24, and that are electrically connected to contact members 40 of a plurality of electrically conductive contact members 40 of the temperature control unit 22 that are arranged on the surface of the widened, trapezoidal end region 30 of the first electrically insulating sheet 24.

The plurality of first electrically conductive tracks 38 has been attached to the first electrically insulating sheet 24 by applying a screen-printing method, using an electrically conductive ink that comprises e.g. silver. Alternative manufacturing methods, such as laminating of copper foil onto the first electrically insulating sheet 24, are also contemplated.

The two surface-mount device (SMD) NTC temperature sensors 34, 36 (or, if applicable, ends of the conductive metal track of the heater member of the alternative temperature control unit) are electrically connected to conductive tracks 38 and are thus electrically connected by the electrically conductive tracks 38 of the plurality of first electrically conductive tracks 38 to contact members 40 of the plurality of electrically conductive contact members 40.

Due to the use of the SMD temperature sensors 34, 36 and the flatness of the plurality of first electrically conductive tracks 38, a total height, as measured in a direction 32 perpendicular to the surfaces of the first electrically insulating sheet 24, of each of the temperature sensors 34, 36, the first electrically conductive tracks 38 that are electrically connected to the respective temperature sensor 34, 36 and the first electrically insulating sheet 24 is less than 1.0 mm.

The control unit 16 is configured for receiving output signals of the two temperature sensors 34, 36 of each one of the plurality of seven temperature control units 22 by electrically connecting input ports of the control unit 16 to the pluralities of the electrically conductive contact members 40. The control unit 16 is configured for monitoring the received temperature sensor output signals and for controlling operation of the cooling means formed by the air blower 20, based on the received temperature sensor output signals and on a fulfillment of a predetermined condition, which is given by a predetermined maximum tolerable temperature level.

In embodiments of the temperature control unit 22 comprising one or more electric heater members, the control unit 16 is further configured for controlling operation of the heating means formed by the electric heater members based on the received temperature sensor output signals, and on a fulfillment of a second predetermined condition, which is given by a predetermined minimum temperature level for an intended efficiency of operation.

FIG. 3 is a perspective view of an alternative temperature control unit 22′ in accordance with another embodiment of the invention. For the sake of brevity, only differences to the embodiment disclosed beforehand will be described.

The alternative temperature control unit 22′ further comprises a contact board 42. The contact board 42 includes an electrically insulating sheet 44 having an even upper surface and an even bottom surface, substantially arranged in parallel to each other, a plurality of second electrically conductive tracks 46 that are arranged on the bottom surface of the electrically insulating sheet 44 and a plurality of three electrically conductive terminal members 48.

Each electrically terminal member 48 of the plurality of electrically conductive terminal members 48 is electrically connected to one of the electrically conductive tracks 46 of the plurality of second electrically conductive tracks 46. As shown in FIG. 3, the contact board 42 is attachable to the first electrically insulating sheet 24 such that each electrically conductive contact member 40 of the plurality of electrically conductive contact members 40 is electrically connected to one of the electrically conductive tracks 46 of the plurality of second of electrically conductive tracks 46. The plurality of three electrically conductive terminal members 48 is arranged in a coplanar manner. The plane of arrangement of the plurality of three electrically conductive terminal members 48 is disposed to form a right angle with the bottom surface of the second electrically insulating sheet 44.

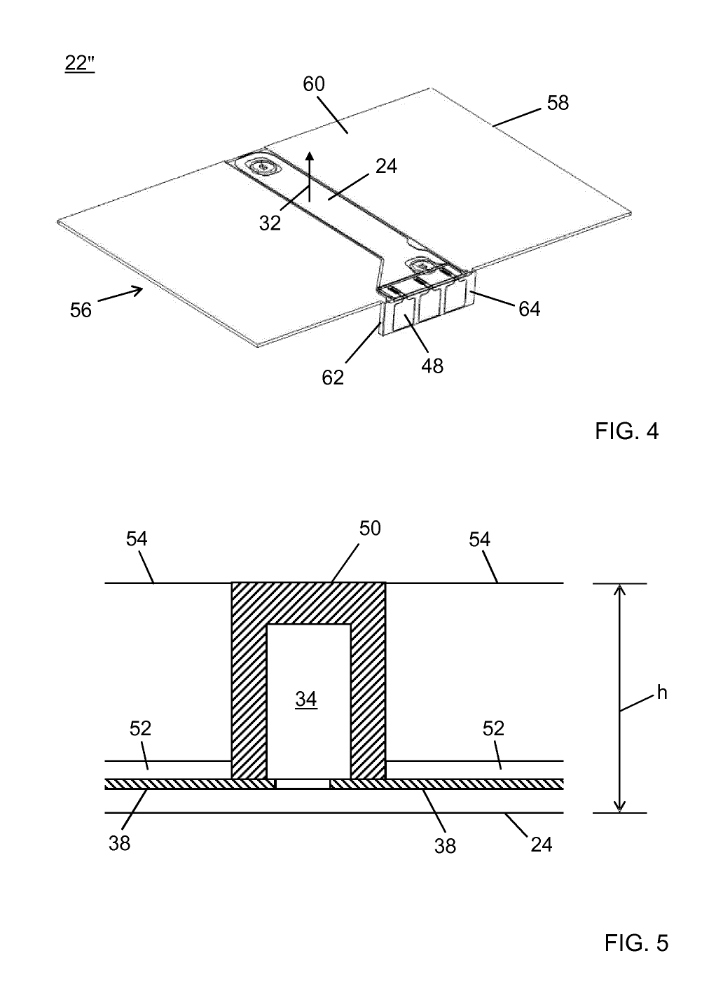

FIG. 4 is a perspective view of another alternative temperature control unit 22″ in accordance with yet another embodiment of the invention. Again, only differences to the embodiments disclosed beforehand will be described.

Compared to the embodiment shown in FIG. 3, the alternative temperature control unit 22″ further comprises a third electrically insulating sheet 56. The third electrically insulating sheet 56 is completely made from PET and comprises a main sheet 58 with even surfaces arranged substantially in parallel to each other, and an edge sheet member 62 that is located at an edge of the main sheet 58.

The first electrically insulating sheet 24 is attached on a top surface 60 of the main sheet 58. The main sheet 58 completely overlaps the first electrically insulating sheet 24 in the direction 32 perpendicular to the surface of the first electrically insulating sheet 24. A surface 64 of the edge sheet member 62 is aligned in parallel to and abutting the plurality of three electrically conductive terminal members 48.

FIG. 5 is a cross-sectional side view of a detail of the alternative temperature control unit 22″. The detail includes one temperature sensor 34 of the SMD NTC temperature sensors 34, 36 electrically connected to two electrically conductive tracks 38 of the plurality of first electrically conductive tracks 38, all of which are arranged on the surface of the first electrically insulating sheet 24.

The temperature sensor 34 comprises an electrically insulating cover 50 comprising UV-curable epoxy resin that is arranged on and adhesively attached to a portion of the temperature sensor 34 that is facing away from the first electrically insulating sheet 24. Such epoxy resin materials are well known for use as “glob-tops” for instance in the field of chip-on-board technology, and are readily commercially available. The resin encapsulation on the temperature sensor 34 supports in withstanding a compression load that is applied to the temperature control unit 22″ in a state of being installed in the battery unit 10 by the compressed block 12 of stacked battery cells.

The electrically conductive tracks 38 of the plurality of first electrically conductive tracks 38 that are electrically connected to the temperature sensor 34 are protected from a corrosive atmosphere existing within the housing of the battery unit 10 by covering with spacers 52 having a thickness of around 100 μm. The temperature control unit 22″ fulfils the requirement for a total height h of the temperature sensor 34, the electrically conductive tracks 38 that are electrically connected to the temperature sensor 38 and the first electrically insulating sheet 24 to be less than or equal to 1.0 mm, as measured in the direction 32 perpendicular to the surfaces of the first electrically insulating sheet 24.

While the invention has been illustrated and described in detail in the drawings and foregoing description, such illustration and description are to be considered illustrative or exemplary and not restrictive; the invention is not limited to the disclosed embodiments.

Other variations to be disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

1. A flat built temperature control unit for use in a rechargeable battery unit comprising at least one stacked battery block, the temperature control unit comprising
at least a first electrically insulating sheet having even, parallel surfaces,
at least one temperature sensor arranged on one of the surfaces of the first electrically insulating sheet,
a plurality of electrically conductive contact members,
a plurality of first electrically conductive tracks that are arranged on a surface of the first electrically insulating sheet,
wherein the at least one temperature sensor is electrically connected by at least some of the plurality of first electrically conductive tracks to at least some of the plurality of electrically conductive contact members.

2. The temperature control unit as claimed in claim 1, wherein a total height (h), as measured in a direction perpendicular to the surfaces of the first electrically insulating sheet, of (i) the at least one temperature sensor, (ii) an electrically conductive track that is electrically connected to the at least one temperature sensor and (iii) the first electrically insulating sheet is less than or equal to 1.0 mm.

3. The temperature control unit as claimed in claim 1, wherein the at least first electrically insulating sheet has a basically oblong shape and the plurality of electrically conductive contact members is arranged on the surface of the first electrically insulating sheet and at an end region of the basically oblong shape.

4. The temperature control unit as claimed in claim 1, wherein the at least one temperature sensor is a surface-mount device NTC temperature sensor.

5. The temperature control unit as claimed in claim 1, wherein the at least one temperature sensor comprises an electrically insulating cover that is at least arranged on and adhesively attached to a portion of the at least one temperature sensor that is facing away from the first electrically insulating sheet.

6. The temperature control unit as claimed in claim 5, wherein the electrically insulating cover is recessed in the area of the temperature sensor, and wherein electrically insulating cover has a thickness that is equal to or higher than a height of the temperature sensor.

7. The temperature control unit as claimed in claim 1, wherein the first electrically conductive tracks that are electrically connected to the at least one temperature sensor are at least partially covered by an electrically insulating coating.

8. The temperature control unit as claimed in claim 1, further comprising a plurality of electrically conductive terminal members, wherein
each electrically conductive terminal member is electrically connected to one of said plurality of first electrically conductive tracks and
the plurality of electrically conductive terminal members is arranged in a coplanar manner, wherein the plane of arrangement is disposed to form a right angle with the bottom surface of the second electrically insulating sheet.

9. The temperature control unit as claimed in claim 1, further comprising a second electrically insulating sheet having a main sheet with even surfaces, arranged in parallel to each other, and an edge sheet member that is located at an edge of the main sheet, wherein
the first electrically insulating sheet is attached on a top surface of the second electrically insulating sheet,
the second electrically insulating sheet overlaps the first electrically insulating sheet in a direction perpendicular to the surface of the first electrically insulating sheet, and
a surface of the edge sheet member is aligned in parallel to and abuts the plurality of electrically conductive terminal members.

10. The temperature control unit as claimed in claim 1, wherein at least part of at least one of the first electrically insulating sheet and the second electrically insulating sheet is made from a plastic material that is selected from a group of plastic materials formed by polyethylene terephthalate PET, polyimide PI, polyetherimide PEI, polyethylene naphthalate PEN, polyoxymethylene POM, polamide PA, polyphthalamide PPA, polyether ether ketone PEEK and combinations of at least two of these plastic materials.

11. The temperature control unit as claimed in claim 1, further comprising at least one further functional element chosen from heater element or current measurement sensor or voltage measurement sensor, said at least one further functional element being arranged on one of the surfaces of the first electrically insulating sheet.

12. A rechargeable electrochemical battery unit, comprising
at least one battery block that includes a plurality of stacked battery cells,
at least one temperature control unit as claimed in claim 1, and
a control unit that is configured for receiving an output signal of at least one temperature sensor and for controlling operation of at least one out of cooling means and heater means based on the received output signal and on fulfillment of at least one predetermined condition.

13. The rechargeable electrochemical battery unit as claimed in claim 12, wherein the at least one battery block comprises a rechargeable lithium ion battery.

14. The rechargeable electrochemical battery unit as claimed in claim 13, wherein the rechargeable lithium ion battery is an automotive battery.
